(19) United States
(12) Patent Application Publication
(10) Pub. No.: US 2006/0157102 A1
(43) Pub. Date: Jul. 20, 2006

(54) Waste heat recovery system and thermoelectric conversion system

(75) Inventors: Kenichiro Nakajima, Chichibu-shi (JP); Nobuhiro Wakabayashi, Oyama-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K.

(21) Appl. No.: 11/329,057

(22) Filed: Jan. 11, 2006

Related U.S. Application Data
(60) Provisional application No. 60/643,724, filed on Jan. 14, 2005.

(30) Foreign Application Priority Data
Jan. 12, 2005 (JP) 2005-004599

(51) Int. Cl. H01L 35/30; H01L 35/28

(52) U.S. Cl. 136/205; 136/204

(57) ABSTRACT

A waste heat recover system includes a mechanism for supplying power by use of a thermoelectric conversion unit, and a mechanism for utilizing heat released from the thermoelectric conversion unit. Heat released from the thermoelectric conversion unit is utilized for, for example, heating, defrosting, defogging, temperature keeping of fuel, temperature keeping of an internal combustion engine, and temperature keeping of a fuel cell. The waste heat recovery system is equipped in, for example, cars, incinerators, fuel cells, and industrial machinery.

### CROSS REFERENCE TO RELATED APPLICATIONS

This application is an application filed under 35 U.S.C. § 111(a) claiming the benefit pursuant to 35 U.S.C. § 119(e)(1) of the filing date of Provisional Application No. 60/643,724 filed Jan. 14, 2005 pursuant to 35 U.S.C. § 111(b).

### BACKGROUND OF THE INVENTION

The present invention relates to a waste heat recovery system in which a thermoelectric conversion unit converts waste heat to electricity and in which warm water is obtained and used for heating, defrosting, or the like.

In the present specification and claims, the term “aluminum” encompasses aluminum alloys in addition to pure aluminum. The upper, lower, left-hand, and right-hand sides of FIG. 2 will be referred to as “upper,” “lower,” “left,” and “right,” respectively. Further, the near side of paper of FIG. 2 (direction indicated by arrow X in FIG. 3) will be referred to as the “front,” and the opposite side as the “rear.

In recent years, awareness of the environment has been growing, and demand for effective means to cope with exhaustion of fossil fuel has been rising; specifically, demand has been rising for as efficient consumption of energy as possible by means of direct conversion of waste heat to electricity by use of a thermoelectric conversion unit.

For example, in the case of an automobile, energy which is used for traveling accounts for only about 15% of energy contained in fuel; energy which is used to generate electricity accounts for 10%; and the remaining energy is released to the atmosphere from the radiator, exhaust gas, an engine housing, and the like in the form of heat.

In order to attain low fuel consumption through effective use of fuel energy, hybrid cars have started to become diffuse. However, since hybrid cars employ numerous pieces of equipment and are of special specifications, diffusion thereof may be limited, and thus contribution thereof to energy conservation is limited.

A most effective measure to conserve energy is effective use of fuel in gasoline or diesel cars, which are currently in wide use. An effective measure to achieve the end is to cut down fuel which is consumed for generating power, by means of recovering waste heat and converting the recovered waste heat to electricity.

Several methods are devised for recovering waste heat. Above all, the Stirling engine, which drives a piston by utilization of waste gas to thereby collect energy, is known to be able to recover energy at high efficiency (refer to Japanese Patent Application Laid-Open (kokai) No. 2004-36499.

A thermoelectric conversion unit has advantages associated with practical application, such as absence of a drive section, immediate generation of power upon occurrence of temperature difference, and simple structure. Research and development of thermoelectric units has been pursued in consideration of mounting in automobiles (refer to Japanese Patent Application Laid-Open (kokai) No. 2004-76046 and Thermoelectric Conversion Unit Technology Review (2004), edited by KAJIKAWA Takenobu et al, published by Realize Corporation).

A conventional thermoelectric conversion unit has employed a radiating heat exchanger for preventing overheat of an entire thermoelectric module. The thus-radiated heat is released to the atmosphere as waste heat without utilization.

Conventional thermoelectric conversion elements are too low in performance to effectively convert heat of exhaust gas to electricity and thus have failed to exhibit sufficient effect. In order to implement highly efficient thermoelectric conversion, a new material must be developed. Further, practical utilization requires development of technology for mass production of high-performance elements.

Since thermal stress causes separation of a thermoelectric conversion element from electrodes with a resultant occurrence of electrical discontinuity, improvement of reliability has been required.

### SUMMARY OF THE INVENTION

An object of the present invention is to provide a waste heat recovery system capable of generating high power.

Another object of the present invention is to provide a thermoelectric conversion unit having excellent thermoelectric conversion efficiency and capable of generating high power.

The present invention has been accomplished on the basis of the above findings and comprises the following modes.

1) A waste heat recovery system having a thermoelectric conversion unit, comprising means for supplying power by use of the thermoelectric conversion unit, and means for utilizing heat released from the thermoelectric conversion unit.

2) A waste heat recovery system according to par. 1), wherein heat released from the thermoelectric conversion unit is utilized for one or more selected from the group consisting of heating, defrosting, defogging, temperature keeping of fuel, temperature keeping of an internal combustion engine, and temperature keeping of a fuel cell.

3) A waste heat recovery system according to par. 1), wherein the thermoelectric conversion unit uses, as a thermoelectric conversion element, a sintered body formed of crystals each having a grain size of 200 μm or less.

4) A waste heat recovery system according to par. 3), wherein the thermoelectric conversion element is obtained by milling an alloy which has been formed by rapid solidification, and sintering the milled alloy.

5) A waste heat recovery system according to par. 3), wherein the thermoelectric conversion element contains crystals of one or more structures selected from the group consisting of half-Heusler structure, Heusler structure, filled skutterudite structure, and skutterudite structure.

6) A thermoelectric conversion unit comprising a high-temperature heat exchanger having a high-temperature fluid channel allowing flow therethrough of a high-temperature fluid having waste heat; a low-temperature heat exchanger having a low-temperature fluid channel allowing flow therethrough of a low-temperature fluid absorbing waste heat released from the high-temperature fluid; a thermoelectric conversion base unit disposed between the high-temperature heat exchanger and the low-temperature heat exchanger; and an electrically insulative plate disposed between the thermoelectric conversion base unit and the high-temperature heat exchanger, and an electrically insulative plate disposed between the thermoelectric conversion base unit and the low-temperature heat exchanger. The thermoelectric conversion base unit comprises a plurality of thermoelectric conversion modules connected in series by electrodes, each thermoelectric conversion module comprising a p-type thermoelectric conversion element and an n-type thermoelectric conversion element, one end portion of the p-type thermoelectric conversion element and one end portion of the n-type thermoelectric conversion element being connected by an electrode. The n- and p-type thermoelectric conversion elements and the electrodes are metal-bonded together; the electrodes and the corresponding electrically insulative plates are metal-bonded together; and the electrically insulative plates and the corresponding high- and low-temperature heat exchangers are metal-bonded together.

7) A thermoelectric conversion unit according to par. 6), wherein the low-temperature heat exchanger is disposed on each of opposite sides of the high-temperature heat exchanger.

8) A thermoelectric conversion unit according to par. 6), wherein the high-temperature heat exchanger comprises a casing defining the high-temperature fluid channel therein and formed of a heat-resistant metal that is not melted by heat of the high-temperature fluid, and a heat-transfer fin disposed in the high-temperature fluid channel of the casing and formed of a heat-resistant metal that is not melted by heat of the high-temperature fluid; the casing has a heat-transfer wall for transferring waste heat from the high-temperature fluid flowing through the high-temperature fluid channel to the p- and n-type thermoelectric conversion elements of the thermoelectric conversion modules of the thermoelectric conversion base unit; the electrically insulative plate made of metal is disposed between the heat-transfer wall and the thermoelectric conversion base unit; a side of the electrically insulative plate which faces the electrodes of the thermoelectric conversion base unit is coated with an electrical-insulator film; and a thermal-stress relaxation portion is provided on each of the heat-transfer wall of the casing and the electrically insulative plate.

9) A thermoelectric conversion unit according to par. 8), wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction.

10) A thermoelectric conversion unit according to par. 8), wherein the thermal-stress relaxation portion comprises a curved portion having a substantially U-shaped cross section, provided on each of the heat-transfer wall of the casing and the electrically insulative plate at such a position as not to interfere with the electrodes, and extending in a front-rear direction.

11) A thermoelectric conversion unit according to par. 8), wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction, and a curved portion having a substantially U-shaped cross section, provided on each of the heat-transfer wall of the casing and the electrically insulative plate at such a position as not to interfere with the electrodes, and extending in a front-rear direction.

12) A thermoelectric conversion unit according to par. 6), wherein the low-temperature heat exchanger comprises a casing defining the low-temperature fluid channel therein and made of aluminum, and a heat-transfer fin disposed in the low-temperature fluid channel of the casing and made of aluminum; the casing has a heat-transfer wall for transferring waste heat from the p- and n-type thermoelectric conversion elements of the thermoelectric conversion base unit to the low-temperature fluid flowing through the low-temperature fluid channel; the electrically insulative plate made of metal is disposed between the heat-transfer wall and the thermoelectric conversion base unit; a side of the electrically insulative plate which faces the electrodes of the thermoelectric conversion base unit is coated with an electrical-insulator film; and a thermal-stress relaxation portion is provided on each of the heat-transfer wall of the casing and the electrically insulative plate.

13) A thermoelectric conversion unit according to par. 12), wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction.

14) A thermoelectric conversion unit according to par. 12), wherein the thermal-stress relaxation portion comprises a curved portion having a substantially U-shaped cross section, provided on each of the heat-transfer wall of the casing and the electrically insulative plate at such a position as not to interfere with the electrodes, and extending in a front-rear direction.

15) A thermoelectric conversion unit according to par. 12), wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction, and a curved portion having a substantially U-shaped cross section, provided on each of the heat-transfer wall of the casing and the electrically insulative plate at such a position as not to interfere with the electrodes, and extending in a front-rear direction.

16) A waste heat recovery system according to par. 1) which is equipped in a vehicle and in which exhaust gas of an engine flows to a high-temperature fluid channel of a high-temperature heat exchanger, and engine cooling water flows to a low-temperature fluid channel of a low-temperature heat exchanger.

17) A car equipped with a waste heat recovery system according to par. 1).

18) A fuel cell system equipped with a waste heat recovery system according to par. 1).

19) An incinerator equipped with a waste heat recovery system according to par. 1).

20) An industrial machine equipped with a waste heat recovery system according to par. 1).

According to the present invention, while, for example, the heat exchanger recovers heat from exhaust gas having a high temperature of up to 950° C. and supplies the heat to the thermoelectric conversion elements, cooling water is circulated on a low-temperature side so as to recover heat released from the thermoelectric conversion elements, thereby establishing a steep thermal gradient. Thus, high power can be obtained.

Heat recovered in cooling water can be used as a heat source for heating or as a heat source for defogging and defrosting in winter, so that further energy conservation effect can be expected.

Usage of warm water recovered by the present system is not limited to heating, defrosting, defogging, and the like; the recovered warm water can also be used for temperature control of an engine and fuel. Thus, further lowering of fuel consumption can be expected.

Application of the present system enables establishment of systems capable of efficiently utilizing various kinds of energy.

Particularly, according to the thermoelectric conversion unit of par. 6), the thermoelectric conversion elements and the electrodes are metal-bonded together; the electrodes and the individual electrically insulative plates are metal-bonded together; and the electrically insulative plates and the corresponding heat exchangers are metal-bonded together. Thus, heat transfer is enhanced between the thermoelectric conversion elements and the high-temperature fluid flowing through the high-temperature fluid channel of the high-temperature heat exchanger and between the thermoelectric conversion elements and the low-temperature fluid flowing through the low-temperature fluid channel of the low-temperature heat exchanger, thereby exhibiting excellent thermoelectric conversion efficiency. Therefore, high power can be obtained.

According to the thermoelectric conversion units of par. 8) and 12), thermal stress is relaxed, the thermal stress being induced by difference in coefficient of linear, thermal expansion and in temperature among the casing of the high-temperature heat exchanger, the casing of the low-temperature heat exchanger, and the thermoelectric conversion elements of the thermoelectric conversion base unit.

According to the thermoelectric conversion units of pars. 9) to 11), a thermal-stress relaxation portion can be provided relatively easily on the heat-transfer wall of the casing of the high-temperature heat exchanger and on the associated electrically insulative plate.

According to the thermoelectric conversion units of pars. 13) to 15), a thermal-stress relaxation portion can be provided relatively easily on the heat-transfer wall of the casing of the low-temperature heat exchanger and on the associated electrically insulative plate.

### BRIEF DESCRIPTION OF THE DRAWINGS

FIG. 1 is a schematic view showing the configuration of a waste heat recovery system equipped in an automobile;

FIG. 2 is a vertical sectional view of a thermoelectric conversion unit;

FIG. 3 is an exploded perspective view showing a portion of the thermoelectric conversion unit; and

FIG. 4 is an exploded perspective view showing a modified embodiment of a thermal-stress relaxation portion of a heat-transfer wall of a low-temperature heat exchanger and a modified embodiment of a thermal-stress relaxation portion of an electrically insulative plate disposed between the low-temperature heat exchanger and a thermoelectric conversion base unit.

### DESCRIPTION OF THE PREFERRED EMBODIMENT

An embodiment of the present invention will next be described in detail with reference to the drawings. The present embodiment is an application of a waste heat recovery system according to the present invention to recovery of waste heat from exhaust gas emitted from an automobile engine.

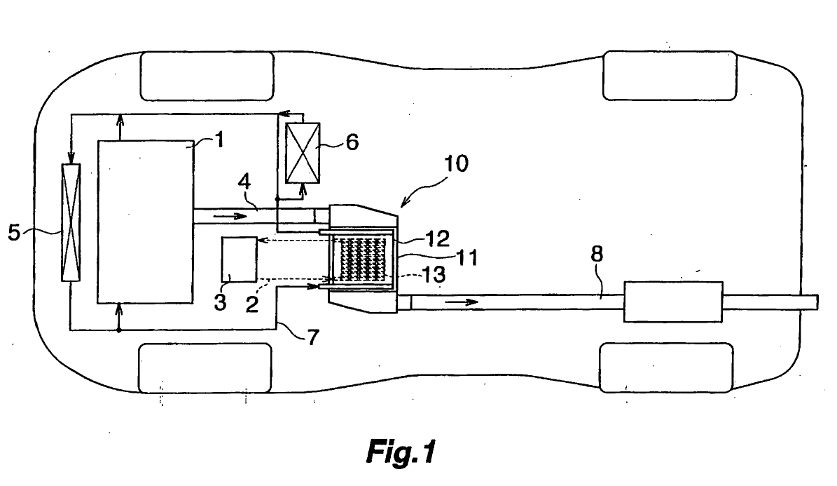

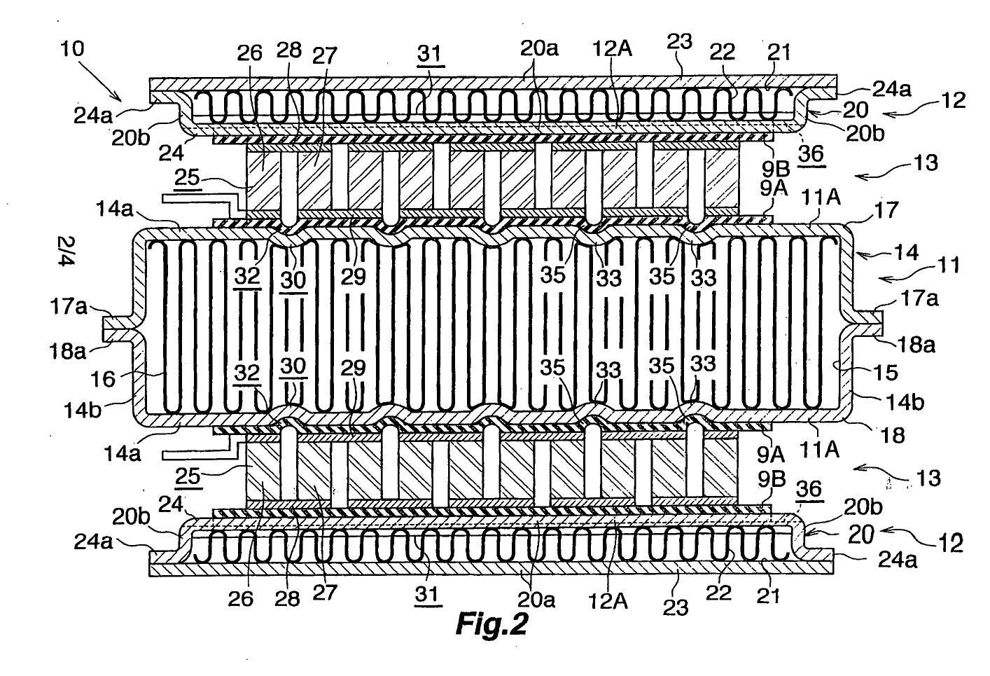

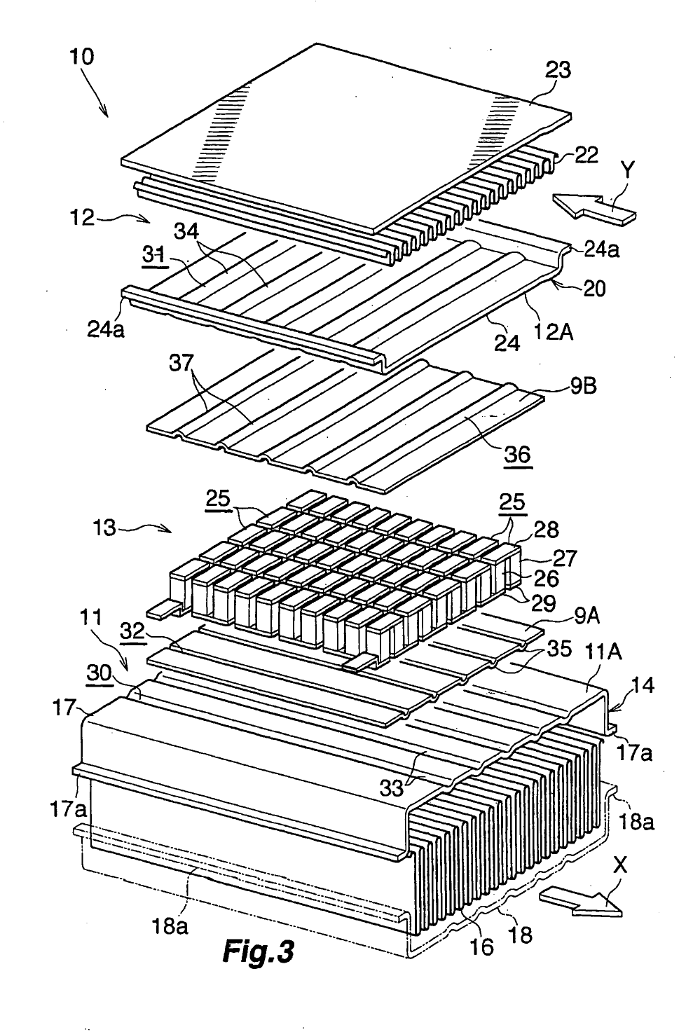

FIG. 1 schematically shows the configuration of the waste heat recovery system equipped in an automobile. FIGS. 2 and 3 specifically shows the configuration of a thermoelectric conversion unit of the waste heat recovery system.

Referring to FIG. 1, the waste heat recovery system includes a thermoelectric conversion unit (10) for converting thermal energy of exhaust gas of an engine (1) to electric energy. The thermoelectric conversion unit (10) is connected to a battery (3) via battery charge wiring (2), so that power generated in the thermoelectric conversion unit (10) is charged to the battery (3).

A high-temperature side of the thermoelectric conversion unit (10) is connected to an exhaust manifold of the engine (1) via exhaust gas piping (4), so that exhaust gas is supplied to the high-temperature side. Exhaust gas which has passed the thermoelectric conversion unit (10) is emitted through an exhaust pipe (8). For example, exhaust gas which has passed a catalyzer and has a temperature of about 600° C. can be employed for this heating purpose. Meanwhile, a low-temperature side of the thermoelectric conversion unit (10) is connected to the engine (1), a radiator (5), and a heater core (6) for an air conditioner via cooling-liquid piping (7), so that an engine cooling liquid cooled by the radiator (5) is supplied to the low-temperature side. As a result, the high-temperature exhaust gas and the low-temperature engine cooling liquid forcibly increase a temperature difference between a high-temperature section and a low-temperature section of the thermoelectric conversion unit (10). Utilizing this temperature difference, the thermoelectric conversion unit (10) generates power.

The heater core (6) connected to the cooling-liquid piping (7) produces hot air for use in heating, defrosting, and defogging by means of using, as heat source, waste heat recovered by the thermoelectric conversion unit (10). By means of connecting a portion of hot-air piping to the engine (1), temperature control can be performed on fuel and an engine housing.

As shown in FIGS. 2 and 3, the thermoelectric conversion unit (10) includes a high-temperature heat exchanger (11); two low-temperature heat exchangers (12) disposed on upper and lower sides, respectively, of the high-temperature heat exchanger (11); two thermoelectric conversion base units (13) disposed between the high-temperature heat exchanger (11) and the respective low-temperature heat exchangers (12); two electrically insulative plates (9A) disposed between the high-temperature heat exchanger (11) and the respective thermoelectric conversion base units (13); and two electrically insulative plates (9B) disposed between the respective low-temperature heat exchangers (12) and thermoelectric conversion base units (13).

The high-temperature heat exchanger (11) includes a casing (14) which defines therein a high-temperature fluid channel (15) extending in the front-rear direction, and a corrugate fin (16) (heat-transfer fin) disposed in the casing (14). Preferably, in order to avoid occurrence of a steep temperature gradient within the thermoelectric conversion unit (10), a dimension of the high-temperature heat exchanger (11) along the direction of exhaust gas flow is rendered as small as possible.

The casing (14) includes upper and lower walls (14a) and left and right side walls (14b), which respectively extend between left side edges of the upper and lower walls (14a) and between right side edges of the upper and lower walls (14a). The upper and lower walls (14a) and the left and right side walls (14b) define the high-temperature fluid channel (15) whose front and rear ends are open. The upper and lower walls (14a) serve as heat-transfer walls (11A) for transferring waste heat from a high-temperature fluid flowing through the high-temperature fluid channel (15) to the thermoelectric conversion base units (13). The exhaust gas piping (4) is connected to a first end of the high-temperature fluid channel (15) of the casing (14) via an unillustrated appropriate duct, whereas the exhaust pipe (8) is connected to a second end of the high-temperature fluid channel (15) via an unillustrated appropriate duct. The casing (14) is composed of an upper component member (17) and a lower component member (18). The upper component member (17) includes the upper wall (14a). Left and right side edge portions of the upper component member (17) are bent downward to thereby form upper half portions of the left and right side walls (14b). The lower component member (18) includes the lower wall (14a). Left and right side edge portions of the lower component member (18) are bent upward to thereby form lower half portions of the left and right side walls (14b). The bent left and right edge portions of the upper and lower component members (17) and (18) have respective end portions bent outward into flange portions (17a) and (18a). The upper and lower component members (17) and (18) are joined together such that the flange portions (17a) and (18a) are metal-bonded together, thereby yielding the casing (14). The upper and lower component members (17) and (18) are formed of a metal which is not melted by heat of exhaust gas flowing through the high-temperature fluid channel (15); for example, stainless steel or copper (including copper alloys; the same is applied to the remainder of the description appearing herein).

The corrugate fin (16) includes wave crest portions, wave trough portions, and horizontal connection portions connecting together the wave crest portions and the wave trough portions. The corrugate fin (16) is disposed in the high-temperature fluid channel (15) such that the wave crest portions and the wave trough portions extend in the front-rear direction. The wave crest portions and the wave trough portions are metal-bonded to the inner surfaces of the upper and lower walls (14a) of the casing (14). The corrugate fin (16) is also formed of a metal which is not melted by heat of exhaust gas flowing through the high-temperature fluid channel (15); for example, stainless steel or copper.

Each of the low-temperature heat exchangers (12) includes a casing (20) which defines therein a low-temperature fluid channel (21) extending in the front-rear direction, and a corrugate fin (22) (heat-transfer fin) disposed in the casing (20).

The casing (20) of the upper low-temperature heat exchanger (12) includes upper and lower walls (20a) and left and right side walls (20b), which respectively extend between left side edges of the upper and lower walls (20a) and between right side edges of the upper and lower walls (20a). The upper and lower walls (20a) and the left and right side walls (20b) define the low-temperature fluid channel (21) whose front and rear ends are open. The lower wall (20a) serves as a heat-transfer wall (12A) for transferring heat from the thermoelectric conversion base unit (13) to a low-temperature fluid which flows through the low-temperature fluid channel (21). A portion of the cooling-liquid piping (7) which extends from the outlet of the radiator (5) is connected to a second end of the low-temperature fluid channel (21) of the casing (20); i.e., to an end corresponding to the second end of the high-temperature fluid channel (15) to which the exhaust pipe (8) is connected. A portion of the cooling-liquid piping (7) which extends to the heater core (6) and the inlet of the radiator (5) is connected to a first end of the low-temperature fluid channel (21); i.e., to an end corresponding to the first end of the high-temperature fluid channel (15) to which the exhaust gas piping (4) is connected. The casing (20) is composed of an upper component member (23) and a lower component member (24). The upper component member (23) includes the upper wall (20a) and assumes a flat-plate-like shape. The lower component member (24) includes the lower wall (20a). Left and right side edge portions of the lower component member (24) are bent upward to thereby form the left and right side walls (20b). The bent left and right edge portions of the lower component member (24) have respective end portions bent outward into flange portions (24a). The upper and lower component members (23) and (24) are joined together such that left and right side edge portions of the upper component member (23) and the corresponding flange portions (24a) of the lower component member (24) are metal-bonded together, thereby yielding the casing (20). The upper and lower component members (23) and (24) are formed of an aluminum plate or the like.

The corrugate fin (22) includes wave crest portions, wave trough portions, and horizontal connection portions connecting together the wave crest portions and the wave trough portions. The corrugate fin (22) is disposed in the low-temperature fluid channel (21) such that the wave crest portions and the wave trough portions extend in the front-rear direction. The wave crest portions and the wave trough portions are metal-bonded; herein, brazed, to the inner surfaces of the upper and lower walls (20a) of the casing (20). The corrugate fin (22) is also formed of an aluminum plate or the like.

The lower low-temperature heat exchanger (12) is of an upside-down orientation of the upper low-temperature heat exchanger (12). Like features or parts are denoted by like reference numerals.

A high-temperature fluid flows through the high-temperature fluid channel (15) of the high-temperature heat exchanger (11) in the direction of arrow X of FIG. 3. A low-temperature fluid flows through the low-temperature fluid channel (21) of the low-temperature heat exchanger (12) in the direction of arrow Y of FIG. 3. The high-temperature fluid and the low-temperature fluid are counterflows.

The thermoelectric conversion base unit (13) is configured such that a plurality of thermoelectric conversion modules (25) are connected in series by means of electrodes (29). Each of the thermoelectric conversion modules (25) is composed of a p-type thermoelectric conversion element (26) and an n-type thermoelectric conversion element (27) which are connected at their end portions by means of an electrode (28). In other words, a plurality of module rows each consisting of a plurality of the thermoelectric conversion modules (25) arranged in the left-right direction are arranged at predetermined intervals in the front-rear direction. All the thermoelectric conversion modules (25) are connected in series by means of the electrodes (29) in a meandering manner and such that the p-type thermoelectric conversion element (26) and the n-type thermoelectric conversion element (27) are alternated with each other, whereby a high voltage can be developed. The electrodes (28) and (29) are formed of, for example, copper. The p- and n-type thermoelectric conversion elements (26) and (27) and the electrodes (28) and (29) are metal-bonded together by use of, for example, a Ti metallization layer formed on each of opposite end surfaces of the thermoelectric conversion elements (26) and (27).

No particular limitation is imposed on the p- and n-type thermoelectric conversion elements (26) and (27) for use in the thermoelectric conversion module (25). Known p- and n-type thermoelectric conversion elements (26) and (27) can be employed. For example, both the p-type thermoelectric conversion element (26) and the n-type thermoelectric conversion element (27) can be of a filled skutterudite sintered body, or at least either the p-type thermoelectric conversion element (26) or the n-type thermoelectric conversion element (27) can be a Zn₃Sb₄ element, a cobalt oxide element, an Mn—Si element, an Mg—Si element, a Bi—Te element, a Pb—Te element, a Heusler material element, a half-Heusler material element, or an Si—Ge material element. These thermoelectric elements can be protected against oxidation with plating or a vapor deposition film.

For example, the p- and n-type thermoelectric conversion elements (26) and (27) can be of a filled-skutterudite-type rare-earth alloy represented by REₓ(Fe_{1-y}M_{y})₄Sb₁₂ (RE is at least one of La and Ce; M is at least one selected from the group consisting of Ti, Zr, Sn, and Pb; 0<x≦1; and 0<y<1). This alloy is preferably used to form the p-type thermoelectric conversion element (26). The alloy can contain unavoidable impurities, such as Pb, As, Si, Al, Fe, Mo, W, C, O, and N, and may assume the form of a thin film, an alloy, or a sintered body. Preferably, the crystal structure is of a skutterudite type. In the above-mentioned rare-earth alloy, when x is less than 0.01, thermal conductivity is impaired with a resultant deterioration in characteristics. When y is in excess of 0.15, Seebeck coefficient and electric conductivity are significantly impaired. Thus, y is preferably 0.15 or less. When y is less than 0.01, the effect of addition in improving performance is insufficient. Thus, y is preferably 0.01 or more. Addition of M in the above-mentioned range can improve both Seebeck coefficient and electric conductivity.

This rare-earth alloy can be manufactured as follows. Materials are measured out so as to attain the composition represented by REₓ(Fe_{1-y}M_{y})₄Sb₁₂ (RE is at least one of La and Ce; M is at least one selected from the group consisting of Ti, Zr, Sn, and Pb; 0<x≦1; and 0<y<1); the materials are melted in an inert-gas atmosphere; and the molten material is rapidly solidified.

The p- and n-type thermoelectric conversion elements (26) and (27) can also be of a rare-earth alloy represented by REₓ(Co_{1-y}M_{y})₄Sb₁₂ (RE is at least one of La and Ce; M is at least one selected from the group consisting of Ti, Zr, Sn, and Pb; 0<x≦1; and 0<y<1). This rare-earth alloy is preferably used to form the n-type thermoelectric conversion element (27). The rare-earth alloy can contain unavoidable impurities, such as Pb, As, Si, Al, Fe, Mo, W, C, O, and N, and may assume the form of a thin film, an alloy, or a sintered body. Preferably, the crystal structure is of a skutterudite type. In the above-mentioned rare-earth alloy, when x is less than 0.01, thermal conductivity is impaired with a resultant deterioration in characteristics. When y is in excess of 0.15, Seebeck coefficient and electric conductivity are significantly impaired. Thus, y is preferably 0.15 or less. When y is less than 0.01, the effect of addition in improving performance is insufficient. Thus, y is preferably 0.01 or more. Addition of M in the above-mentioned range can improve mainly Seebeck coefficient, so that performance can be improved.

This rare-earth alloy can be manufactured as follows. Materials are measured out so as to attain the composition represented by REₓ(Co_{1-y}M_{y})₄Sb₁₂ (RE is at least one of La and Ce; M is at least one selected from the group consisting of Ti, Zr, Sn, and Pb; 0<x≦1; and 0<y<1); the materials are melted in an inert-gas atmosphere; and the molten material is rapidly solidified.

A strip casting process or a known process for rapidly cooling molten metal can be used for rapidly cooling the above-mentioned two alloys. These cooling rates for a range of 1,400° C. to 800° C. are preferably 1×10²° C./sec or more, more preferably 1×10²° C./sec to 1×10⁴° C./sec, far more preferably 2×10²° C./sec to 1×10³° C./sec. When the cooling rates are less than 1×10²° C./sec, phases are separated from one another, so that variations in components upon milling increase. When the cooling rates are greater than 1×10⁴° C./sec, the structure becomes amorphous, causing impairment in milling efficiency.

Employment of such a rapid cooling process imparts an average thickness of about 0.1 mm to 2 mm to alloy flakes. Employment of a preferable rapid cooling rate imparts an average thickness of about 0.2 mm to 0.4 mm. Employment of a most preferable rapid cooling rate imparts an average thickness of about 0.25 mm to 0.35 mm.

A Heusler alloy is represented by the general formula A_{3-X}B_{X}C, where A and B are transition metals; C is a metal of Group III or IV; and the space group is Fm3m. A half-Heusler alloy is represented by the general formula ABC, where A and B are transition metals; C is a metal of Group III or IV; and the space group is F43m.

Electrical and thermal properties of the above-mentioned Heusler alloys and half-Heusler alloys can be adjusted by adding, as an additive to the alloys, B, C, Mg, Cu, or Zn, or a rare-earth metal such as Y, La, Ce, Nd, Pr, Dy, Tb, Ga, or Yb. In the preferred embodiment of the present invention, the highest peak ratio of the Heusler or half-Heusler phase is preferably 85% or more, more preferably 90% or more. The peak ratio is defined by IHS/(IHS+IA+IB)×100 (%), where IHS is the highest peak of the Heusler or half-Heusler phase; IA is the highest peak strength of an impurity phase A; IB is the highest peak strength of an impurity phase B; and IHS, IA, and IB are measured by powder X-ray diffractometry.

In order that the composition after casting becomes half-Heusler (TiₓZr₁₋ₓ) NiSn (0≦x≦1), these Heusler alloys are manufactured, for example, as follows: sponge Ti (purity 99% or higher), sponge Zr (purity 99% or higher), electrolytic Ni (purity 99% or higher), and Sn metal (purity 99.9% or higher) are measured out; the thus-prepared materials are radio-frequency-melted in an Ar atmosphere of 0.1 MPa to 1,700° C.; and the molten material is rapidly solidified.

No particular limitation is imposed on a milling process for milling an alloy. Known milling processes can be employed. For example, a ball mill, a pot mill, an attritor, a pin mill, or a jet mill can be used for milling. For example, the jet mill is preferred for the following reason: although the jet mill is relatively high in milling cost, it allows continuous operation, allows a user to readily take preventive measures against oxidation and dust explosion, and can yield a fine powder having a particle size of about 20 μm in a relatively short period of time. Since a rapidly solidified alloy exhibits good millability, a fine powder having a particle size of 20 μm or less can be produced in a shorter period of time at high yield.

No particular limitation is imposed on a forming process for an alloy. For example, a powder having a particle size of several μm which has been obtained by fine milling is compacted at a pressure of 0.5 t/cm² to 5.0 t/cm² to thereby obtain a green compact. The green compact is subjected to ambient-pressure liquid-phase sintering in an inert atmosphere at a temperature immediately below the melting point of the alloy, thereby yielding a thermoelectric element composed of fine crystal grains having a grain size of 100 μm or less. In view of a drop in thermal conductivity caused by lattice scattering, the smaller the grain size of the thermoelectric element, the better. The grain size of the thermoelectric element is preferably 100 μm or less, more preferably 10 μm to 15 μm, which enables attainment of high performance by virtue of thermal scattering at grain boundaries.

The p- and n-type thermoelectric conversion elements (26) and (27) and the electrodes (28) and (29) may be electrically connected as follows: metal caps are respectively fitted to opposite end portions of the thermoelectric conversion elements (26) and (27), and the electrodes (28) and (29) are electrically connected to the cap-fitted thermoelectric conversion elements (26) and (27).

No particular limitation is imposed on material for the metal caps. Preferably, the caps are formed of a material whose coefficient of thermal expansion is equal to or less than that of a substance used to form the thermoelectric conversion elements (26) and (27). For example, stainless steel, copper, iron, silver, gold, or the like can be used to form the caps for the thermoelectric conversion elements (26) and (27) having a large coefficient of thermal expansion. Molybdenum, zirconium, titanium, tungsten, or the like can be used to form the caps for the thermoelectric conversion elements (26) and (27) having a small coefficient of thermal expansion. Filling a space between the cap and each of the thermoelectric conversion elements (26) and (27) with alloy or metal particles which are liquefied at high temperature effectively prevents occurrence of a clearance therebetween which would otherwise result from temperature rise.

No particular limitation is imposed on the shape of the metal caps, but a cylindrical shape is preferred. The bottom of each of the caps may be flat or curved. Preferably, the height of the caps is equal to or less than that of the thermoelectric conversion elements (26) and (27). A fine hole may be formed in the bottoms of the caps, or a groove may be formed on the side walls of the caps, so as to release air remaining in clearances between the caps and the thermoelectric conversion elements (26) and (27) having expanded as a result of temperature rise.

The caps and the electrodes (28) and (29) can be metal-bonded together by, for example, heating to 700° C. while using silver brazing filler material. However, the caps can be bonded to the electrodes (28) and (29) beforehand, whereby productivity can be further improved. The electrodes (28) and (29) and the caps can be formed integrally. If necessary, each of the caps is covered with a metal or an electrically conductive ceramic which serves as an anti-diffusion layer, or such a material is used as a cap, whereby a process of covering the thermoelectric conversion elements (26) and (27) with such a material can be omitted with a resultant further improvement in productivity.

The electrically insulative plates (9A) and (9B) are configured such that a metal plate is coated with an electrical-insulator film on at least one side. The thickness of the electrical-insulator film is preferably about 100 nm. The electrically insulative plates (9A) and (9B) are metal-bonded to the heat-transfer wall (11A) of the high-temperature heat exchanger (11) and the heat-transfer wall (12A) of the low-temperature heat exchanger (12), respectively, while the electrical-insulator films thereof face the thermoelectric conversion module (25). The electrodes (29) and (28) are metal-bonded to the electrical-insulator films of the electrically insulative plates (9A) and (9B), respectively.

The heat-transfer walls (11A) of the high-temperature heat exchanger (11), the heat-transfer walls (12A) of the low-temperature heat exchangers (12), and the electrically insulative plates (9A) and (9B) are provided with thermal-stress relaxation portions (30), (31), (32), and (36), respectively. The thermal-stress relaxation portions (30), (31), (32), and (36) relax thermal stress which is induced by difference in coefficient of linear, thermal expansion and in temperature among the casing (14) of the high-temperature heat exchanger (11), the casings (20) of the low-temperature heat exchangers (12), and the p- and n-type thermoelectric conversion elements (26) and (27) of the thermoelectric conversion base units (13).

The thermal-stress relaxation portion (30) of the heat-transfer wall (11A) of the high-temperature heat exchanger (11) includes a plurality of curved portions (33) each having a substantially U-shaped cross section which are formed at predetermined intervals in the left-right direction, extend in the front-rear direction, and project toward the interior of the casing (14). Each of the curved portions (33) is located between the electrodes (29) each of which connects the thermoelectric conversion modules (25) located adjacent to each other in the left-right direction.

The thermal-stress relaxation portion (32) of the electrically insulative plate (9A) disposed between the high-temperature heat exchanger (11) and the thermoelectric conversion base unit (13) includes a plurality of curved portions (35) each having a substantially U-shaped cross section which are formed at predetermined intervals in the left-right direction, extend in the front-rear direction, and project toward the high-temperature heat exchanger (11). The curved portions (35) correspond, in terms of position, to the curved portions (33) of the heat-transfer wall (11A) of the high-temperature heat exchanger (11).

The thermal-stress relaxation portion (31) of the heat-transfer wall (12A) of the low-temperature heat exchanger (12) includes a plurality of curved portions (34) each having a substantially U-shaped cross section which are formed at predetermined intervals in the front-rear direction, extend in the left-right direction, and project toward the interior of the casing (20). Each of the curved portions (34) is located between the module rows located adjacent to each other in the front-rear direction.

The thermal-stress relaxation portion (36) of the electrically insulative plate (9B) disposed between the low-temperature heat exchanger (12) and the thermoelectric conversion base unit (13) includes a plurality of curved portions (37) each having a substantially U-shaped cross section which are formed at predetermined intervals in the front-rear direction, extend in the left-right direction, and project toward the low-temperature heat exchanger (12). The curved portions (37) correspond, in terms of position, to the curved portions (34) of the heat-transfer wall (12A) of the low-temperature heat exchanger (12).

Accordingly, the thermal-stress relaxation portions (32) and (36) of the electrically insulative plates (9A) and (9B) and the thermal-stress relaxation portions (30) and (31) of the heat-transfer walls (11A) and (12A) of the high- and low-temperature heat exchangers (11) and (12) are formed in such a manner as not to interfere with the electrodes (28) and (29).

In the above-described waste heat recovery system, high-temperature exhaust gas emitted from the engine (1) flows to the high-temperature heat exchanger (11) of the thermoelectric conversion unit (10) through the exhaust gas piping (4); passes through the high-temperature fluid channel (15) in the direction of arrow X of FIG. 3; and is emitted to the atmosphere through the exhaust pipe (8). While the high-temperature exhaust gas is flowing through the high-temperature fluid channel (15) of the high-temperature heat exchanger (11), heat of the high-temperature exhaust gas is transferred to the p- and n-type thermoelectric conversion elements (26) and (27) via the corrugate fin (16), the heat-transfer walls (11A), the electrically insulative plates (9A), and the electrodes (29), thereby heating a high-temperature side of the thermoelectric conversion elements (26) and (27). Meanwhile, low-temperature cooling liquid outflowing from the radiator (5) flows to the low-temperature heat exchangers (12) of the thermoelectric conversion unit (10) through the cooling-liquid piping (7); passes through the low-temperature fluid channels (21) in the direction of arrow Y of FIG. 3; and flows to the heater core (6) through the cooling-liquid piping (7). While the cooling liquid is flowing through the low-temperature fluid channels (21) of the low-temperature heat exchangers (12), heat emitted from the p- and n-type thermoelectric conversion elements (26) and (27) is transferred to the cooling liquid via the corrugate fins (22), the heat-transfer walls (12A), the electrically insulative plates (9B), and the electrodes (28), thereby cooling a low-temperature side of the thermoelectric conversion elements (26) and (27). Accordingly, a large temperature difference arises between the high-temperature side and the low-temperature side of the p- and n-type thermoelectric conversion elements (26) and (27), whereby voltage is developed (Seebeck effect); i.e., thermoelectromotive force is generated, thereby generating power. Meanwhile, the cooling liquid which is heated by heat emitted from the p- and n-type thermoelectric conversion elements (26) and (27) flows to the heater core (6). The heater core (6) produces warm air by using, as a heat source, waste heat which is recovered from the p- and n-type thermoelectric conversion elements (26) and (27) via the heated cooling water. The thus-produced warm air is utilized for, for example, heating, defrosting, and defogging.

The thermal-stress relaxation portions (30), (31), and (32) of the above-described embodiment can be modified as follows. Although unillustrated, the thermal-stress relaxation portion (30) of the heat-transfer wall (11A) of the high-temperature heat exchanger (11) includes a plurality of curved portions each having a substantially U-shaped cross section which are formed at predetermined intervals in the front-rear direction, extend in the left-right direction, and project toward the interior of the casing (14). Each of the curved portions is located between the module rows located adjacent to each other in the front-rear direction. In this case, the thermal-stress relaxation portions (31) and (32) of the heat-transfer wall (12A) and the electrically insulative plate (9A) of the low-temperature heat exchanger (12) each include a plurality of curved portions each having a substantially U-shaped cross section which are formed at predetermined intervals in the left-right direction, extend in the front-rear direction, and project toward the interior of the casing (20). Each of the curved portions is located between the electrodes (28) of the thermoelectric conversion modules (25) located adjacent to each other in the left-right direction.

The thermal-stress relaxation portions (30), (31), and (32) can be further modified as follows. Although unillustrated, the thermal-stress relaxation portion (30) of the heat-transfer wall (11A) of the high-temperature heat exchanger (11) includes a plurality of first curved portions each having a substantially U-shaped cross section which are formed at predetermined intervals in the left-right direction, extend in the front-rear direction, and project toward the interior of the casing (14), and a plurality of second curved portions each having a substantially U-shaped cross section which are formed at predetermined intervals in the front-rear direction, extend in the left-right direction, and project toward the interior of the casing (14). Each of the first curved portions is located between the electrodes (29) each of which connects the thermoelectric conversion modules (25) located adjacent to each other in the left-right direction. Each of the second curved portions is located between the module rows located adjacent to each other in the front-rear direction. In this case, the thermal-stress relaxation portion (32) of the electrically insulative plate (9A) disposed between the high-temperature heat exchanger (11) and the thermoelectric conversion base unit (13) includes a plurality of first curved portions each having a substantially U-shaped cross section which are formed at predetermined intervals in the left-right direction, extend in the front-rear direction, and project toward the high-temperature heat exchanger (11), and a plurality of second curved portions each having a substantially U-shaped cross section which are formed at predetermined intervals in the front-rear direction, extend in the left-right direction, and project toward the high-temperature heat exchanger (11). The first and second curved portions of the electrically insulative plate (9A) correspond, in terms of position, to the first and second curved portions of the heat-transfer wall (11A) of the high-temperature heat exchanger (11).

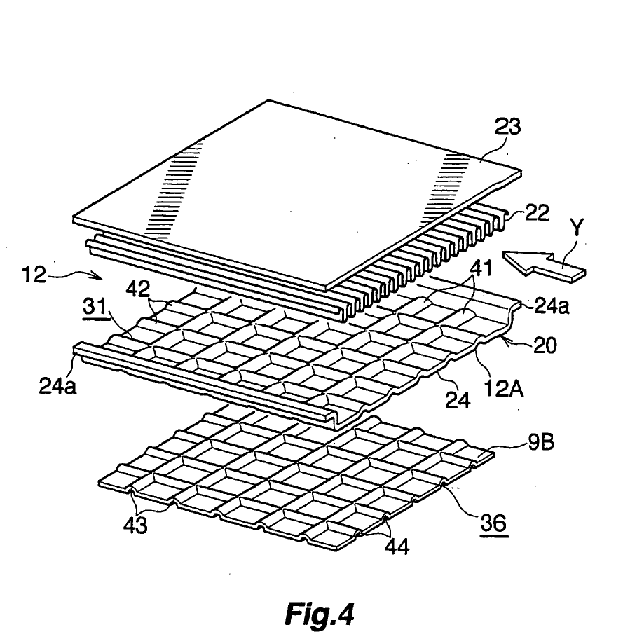

As shown in FIG. 4, the thermal-stress relaxation portion (31) of the heat-transfer wall (12A) of the low-temperature heat exchanger (12) includes a plurality of first curved portions (41) each having a substantially U-shaped cross section which are formed at predetermined intervals in the front-rear direction, extend in the left-right direction, and project toward the interior of the casing (20), and a plurality of second curved portions (42) each having a substantially U-shaped cross section which are formed at predetermined intervals in the left-right direction, extend in the front-rear direction, and project toward the interior of the casing (20). Each of the first curved portions (41) is located between the module rows located adjacent to each other in the front-rear direction. Each of the second curved portions (42) is located between the electrodes (28) of the thermoelectric conversion modules (25) located adjacent to each other in the left-right direction. In this case, the thermal-stress relaxation portion (36) of the electrically insulative plate (9B) disposed between the low-temperature heat exchanger (12) and the thermoelectric conversion base unit (13) includes a plurality of first curved portions (43) each having a substantially U-shaped cross section which are formed at predetermined intervals in the front-rear direction, extend in the left-right direction, and project toward the low-temperature heat exchanger (12), and a plurality of second curved portions (44) each having a substantially U-shaped cross section which are formed at predetermined intervals in the left-right direction, extend in the front-rear direction, and project toward the low-temperature heat exchanger (12). The first and second curved portions (43) and (44) correspond, in terms of position, to the first and second curved portions (41) and (42) of the heat-transfer wall (12A) of the low-temperature heat exchanger (12).

In the above-described embodiment, the heat-transfer walls (12A) of the low-temperature heat exchangers (12) and the electrically insulative plates (9B) disposed between the respective low-temperature heat exchangers (12) and thermoelectric conversion base units (13) have respective thermal-stress relaxation portions formed thereon. However, these thermal-stress relaxation portions are not necessarily required.

The waste heat recovery system of the above-described embodiment employs a single thermoelectric conversion unit. However, the present invention is not limited thereto. The number of thermoelectric conversion units can be modified as appropriate.

Further, in the above-described embodiment, the casing (14) of the high-temperature heat exchanger (11) is formed of a metal which is not melted by heat of exhaust gas flowing through the high-temperature fluid channel (15). However, a known ceramic may be used to form the casing (14). Examples of such ceramics which are preferred in view of heat resistance, thermal shock resistance, and thermal conductivity include silicon carbide, silicon nitride, sialon, aluminum nitride, titanium nitride, and titanium diboride. Above all, silicon carbide is particularly preferred. In this case, Ni or Ti is used to bond together the heat-transfer wall of the high-temperature heat exchanger (11) and the electrically insulative plate (9A). Additionally, a cushion layer can be provided as needed therebetween for relaxing stress.

Power recovered by the present system may be supplied to a battery to thereby be indirectly reused, may be used to directly drive an oil hydraulic pump or the like, or may be used as an electric source for electrochemical reactions in exhaust gas purification.

Further, the waste heat recovery system according to the present invention is employed not only in automobiles but also in fuel cell systems, incinerators, industrial machinery, and the like.

What is claimed is:

1. A waste heat recovery system having a thermoelectric conversion unit, comprising means for supplying power by use of the thermoelectric conversion unit, and means for utilizing heat released from the thermoelectric conversion unit.

2. A waste heat recovery system according to claim 1, wherein heat released from the thermoelectric conversion unit is utilized for one or more selected from the group consisting of heating, defrosting, defogging, temperature keeping of fuel, temperature keeping of an internal combustion engine, and temperature keeping of a fuel cell.

3. A waste heat recovery system according to claim 1, wherein the thermoelectric conversion unit uses, as a thermoelectric conversion element, a sintered body formed of crystals each having a grain size of 200 μm or less.

4. A waste heat recovery system according to claim 3, wherein the thermoelectric conversion element is obtained by milling an alloy which has been formed by rapid solidification, and sintering the milled alloy.

5. A waste heat recovery system according to claim 3, wherein the thermoelectric conversion element contains crystals of one or more structures selected from the group consisting of half-Heusler structure, Heusler structure, filled skutterudite structure, and skutterudite structure.

6. A thermoelectric conversion unit comprising:
a high-temperature heat exchanger having a high-temperature fluid channel allowing flow therethrough of a high-temperature fluid having waste heat;
a low-temperature heat exchanger having a low-temperature fluid channel allowing flow therethrough of a low-temperature fluid absorbing waste heat released from the high-temperature fluid;
a thermoelectric conversion base unit disposed between the high-temperature heat exchanger and the low-temperature heat exchanger; and
an electrically insulative plate disposed between the thermoelectric conversion base unit and the high-temperature heat exchanger, and an electrically insulative plate disposed between the thermoelectric conversion base unit and the low-temperature heat exchanger;
wherein the thermoelectric conversion base unit comprises a plurality of thermoelectric conversion modules connected in series by electrodes, each thermoelectric conversion module comprising a p-type thermoelectric conversion element and an n-type thermoelectric conversion element, one end portion of the p-type thermoelectric conversion element and one end portion of the n-type thermoelectric conversion element being connected; and
the n- and p-type thermoelectric conversion elements and the electrodes are metal-bonded together, the electrodes and the corresponding electrically insulative plates are metal-bonded together, and the electrically insulative plates and the corresponding high- and low-temperature heat exchangers are metal-bonded together.

7. A thermoelectric conversion unit according to claim 6, wherein the low-temperature heat exchanger is disposed on each of opposite sides of the high-temperature heat exchanger.

8. A thermoelectric conversion unit according to claim 6, wherein the high-temperature heat exchanger comprises a casing defining the high-temperature fluid channel therein and formed of a heat-resistant metal that is not melted by heat of the high-temperature fluid, and a heat-transfer fin disposed in the high-temperature fluid channel of the casing and formed of a heat-resistant metal that is not melted by heat of the high-temperature fluid;
the casing has a heat-transfer wall for transferring waste heat from the high-temperature fluid flowing through the high-temperature fluid channel to the p- and n-type thermoelectric conversion elements of the thermoelectric conversion modules of the thermoelectric conversion base unit;
the electrically insulative plate made of metal is disposed between the heat-transfer wall and the thermoelectric conversion base unit;
a side of the electrically insulative plate which faces the electrodes of the thermoelectric conversion base unit is coated with an electrical-insulator film; and
a thermal-stress relaxation portion is provided on each of the heat-transfer wall of the casing and the electrically insulative plate.

9. A thermoelectric conversion unit according to claim 8, wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction.

10. A thermoelectric conversion unit according to claim 8, wherein the thermal-stress relaxation portion comprises a curved portion having a substantially U-shaped cross section, provided on each of the heat-transfer wall of the casing and the electrically insulative plate at such a position as not to interfere with the electrodes, and extending in a front-rear direction.

11. A thermoelectric conversion unit according to claim 8, wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction, and a curved portion having a substantially U-shaped cross section, provided on each of the heat-transfer wall of the casing and the electrically insulative plate at such a position as not to interfere with the electrodes, and extending in a front-rear direction.

12. A thermoelectric conversion unit according to claim 6, wherein the low-temperature heat exchanger comprises a casing defining the low-temperature fluid channel therein and made of aluminum, and a heat-transfer fin disposed in the low-temperature fluid channel of the casing and made of aluminum;
the casing has a heat-transfer wall for transferring waste heat from the p- and n-type thermoelectric conversion elements of the thermoelectric conversion base unit to the low-temperature fluid flowing through the low-temperature fluid channel;
the electrically insulative plate made of metal is disposed between the heat-transfer wall and the thermoelectric conversion base unit;
a side of the electrically insulative plate which faces the electrodes of the thermoelectric conversion base unit is coated with an electrical-insulator film; and
a thermal-stress relaxation portion is provided on each of the heat-transfer wall of the casing and the electrically insulative plate.

13. A thermoelectric conversion unit according to claim 12, wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction.

14. A thermoelectric conversion unit according to claim 12, wherein the thermal-stress relaxation portion comprises a curved portion having a substantially U-shaped cross section, provided on each of the heat-transfer wall of the casing and the electrically insulative plate at such a position as not to interfere with the electrodes, and extending in a front-rear direction.

15. A thermoelectric conversion unit according to claim 12, wherein the thermal-stress relaxation portion comprises a curved portion having a substantially U-shaped cross section, provided on each of the heat-transfer wall of the casing and the electrically insulative plate at such a position as not to interfere with the electrodes, and extending in a left-right direction, and a curved portion having a substantially U-shaped cross section, provided on each of the heat-transfer wall of the casing and the electrically insulative plate at such a position as not to interfere with the electrodes, and extending in a front-rear direction.

16. A waste heat recovery system according to claim 1 which is equipped in a vehicle and in which exhaust gas of an engine flows to a high-temperature fluid channel of a high-temperature heat exchanger, and engine cooling water flows to a low-temperature fluid channel of a low-temperature heat exchanger.

17. A car equipped with a waste heat recovery system according to claim 1.

18. A fuel cell system equipped with a waste heat recovery system according to claim 1.

19. An incinerator equipped with a waste heat recovery system according to claim 1.

20. An industrial machine equipped with a waste heat recovery system according to claim 1.
